(19) United States
(12) Patent Application Publication
(10) Pub. No.: US 2008/0246645 A1
(43) Pub. Date: Oct. 9, 2008

(54) Folding Circuit

(75) Inventor: Peter Cornelis Simeon Scholtens, Nijmegen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/093,660

(22) PCT Filed: Nov. 7, 2006
(86) PCT No.: PCT/IB06/54146

§ 371 Date: May 14, 2008

(30) Foreign Application Priority Data
Nov. 17, 2005 (EP) 05110905.6

(51) Int. Cl. H03M 1/36

(52) U.S. Cl. 341/155

(57) ABSTRACT

A switchable folding circuit for an analog-to-digital converter is provided. The switchable folding circuit comprises a plurality of circuit stages wherein each of the circuit stages comprises a differential pair, a current source and a switching unit. The differential pair is connected to the current source via the switching unit and the circuit stages are inversely connected to one another.

The invention relates to the field of folding circuits. In particular, the invention relates to a switchable folding circuit, to an analog-to-digital converter comprising a switchable folding circuit and to a method of operating a switchable folding circuit.

In digital data processing, converting analog signals into digital or binary representations is an important issue. For converting analog signals into digital signals different analog-to-digital converter (ADC) architectures are known. One method to convert an analog signal to a digital representation is to compare the analog input continuously with a set of a predefined reference values, e.g. voltages. Such kind of an ADC is implemented in a flash ADC. In flash ADCs, analog input signals are compared with different thresholds, in order to receive the digital value at any time.

A further known architecture for ADCs are so-called folding ADCs. One example for a folding ADC is published in WO 2005/01125 A1. Further examples of folding ADCs are known from LP 0 227 165 A2 and R. van der Grift et al, “A monolithic 8-bit Video A/D converter”, IEEE Journal of Solid-State Circuits, June 1984, pp. 374-378

The many parallel folding branches in the general folding architecture can be reduced by stacking the differential pairs, as can be seen in WO 2005/01125 A1. This will reduce the overall power consumption and reduce the number of offset contributors.

The first limitation of WO 2005/01125 A1 is the obligation for a tree like structure limiting the number of pairs to rather awkward numbers 3, 7, . . . (2ⁿ)−1. The second limitation of WO 2005/01125 A1 is the requirement to select the proper connection by using voltage controlled switches, which cannot be driven quickly enough.

Concerning the efficiency, the different methods for converting an analog signal into a digital signal are compared by performance parameters. Examples for performance parameters are the resolution speed, the amplification and the power consumption of the corresponding ADC.

In most cases the price to pay for improving one performance parameters is the degradation of another performance parameter.

The following prior art documents might be helpful for improving the understanding of the present invention:
Rudy van de Plassche, “Integrated Analog-to-digital and Digital-to-analog Converters.”, Kluwer Academic Publishers, 1994.
Hoogzaad, G., Roovers, R., “A 65-mW, 10-bit 40-Msample/s BiCMOS Nyquist ADC in 0.8 mm2.”, IEEE Journal of Solid-State Circuits, vol. 34, No. 12, December 1999 pp. 1796-1802
Gray, P. R., Meyer, R. G., “Analysis and Design of Analog Integrated Circuits”, John wiley and Sons, Inc., 1977-93, pp. 670-675
Scholtens, P. C. S., Vertregt, M., “A 6b 1.6 GS/s Flash ADC in 0.18 μm CMOS using averaging termination.”, IEEE Journal of Solid-State Circuits, December 2002, vol. 37, no. 12, pp. 1599-1610
U.S. Pat. No. 5,751,236
U.S. Pat. No. 6,236,348
U.S. Pat. No. 5,392,045
Valburg J. van, Plassche, R. J. van de, “An 8-bit 650 MHz Folding ADC”, IEEE Journal of Solid-State Circuits, vol. 27, no. 12, December 1992

It may be desirable to have an improved folding circuit, particular for use with an analog digital converter.

According to an exemplary embodiment of the present invention, a switchable folding circuit for generating an output signal based on an input signal is provided. The switchable folding circuit comprises a plurality of circuit stages. Each of the circuit stages comprises a switching unit, a current source and a differential pair, wherein each of the differential pairs comprises an input terminal, which input terminal is adapted to receive the input signal which may be analog and an output terminal, which output terminal is adapted to provide the output signal.

Each differential pair of a circuit stage is connected to the current source via the switching unit. There may be a plurality of circuit stages, wherein the circuit stages are placed next to each other, wherein each circuit stage may be inversely connected to one another.

In this context, the term “inversely connected” may particularly denote that two output connections related to two transistors (first transistor and second transistor) of the differential pairs are connected in the following manner: the outputs of the first transistors of circuit stages having an even number are connected to one another and are connected to the outputs of the second transistors of circuit stages having an odd number; correspondingly, the outputs of the first transistors of circuit stages having an odd number are connected to one another and are connected to the outputs of the second transistors of circuit stages having an even number.

In other words, a differential pair may comprise two transistors. Transistors in the context of this text can be any transistor. Examples for transistors are bipolar transistor, FET (field effect transistor) in any form, either as MOSFET (metal oxide semiconductor field-effect transistor), NMOS, PMOS or JFET.

A transistor may provide three terminals. These three terminals are called basis, collector and emitter in the case of a bipolar transistor and gate, drain and source in the case of a field effect transistor. The terms “source” and “drain” as transistor terminals may be exchanged, or might be denoted as “source-/drain” terminals.

The bipolar transistors may be available as NPN or PNP transistors, whereas MOSFET transistors may be available as N-channel and P-channel. This application may use but is not limited to N-channel MOSFET transistors. In order to increase the output impedance of a transistor a cascoded arrangement of a plurality of transistors may also be used.

A differential pair may be built if the sources of two transistors are directly connected. An input signal may be applied to the gates of the two transistors of a differential pair.

The gate of each of the transistors may provide an input terminal for the relevant differential pair. Since a differential pair may comprises two transistors, a differential pair may provide two input terminals.

An input signal may be supplied to a first input terminal of the differential pair and an inverse signal may be provided to the other input terminal of a differential pair.

The drain of the transistors may provide an output terminal of each of the differential pairs. Thus, a differential pair may have two output terminals.

A plurality of differential pairs i.e. a plurality of circuit stages may be placed next to each other. These differential pairs may build neighbours and may be connected to one another. Then the first output terminal of the first circuit stage may be connected to the second output of the second circuit stage and the second output of the first circuit stage may be connected to the first output of the second circuit stage. This scheme may be continued for each connected circuit stage.

Since the signal provided by the first output of the first circuit stage and the signal provided by the second output of the first circuit stage may be inverse signals, the scheme of alternately connecting the outputs of the different circuit stages may be called an inverse connection of the circuit stages.

Each circuit stage may consist of exactly one differential pair, exactly one current source and exactly one switching unit. It is possible that different circuit stages do not share any common members or components. Particularly, it is possible that different differential pairs do not share a common current source.

Using a switchable folding circuit, wherein the outputs of the differential pairs are inversely connected to one another and wherein the differential pairs are connected via a switch to a current source, may provide a folding signal at its output terminals wherein the folding ratio may be any number. A comparator array or amplifier array may be a analog pre-processing unit providing comparators in order to compare an input signal with a predefined number of reference values.

The folding ratio or folding factor expresses how many times the comparator array may be used on the input range, or how many parallel differential folding pairs may be present. For example, the folding ratio may be a power of two.

A switchable folding circuit may also provide an output signal, wherein the amplification is not reduced with the folding factor of the circuit. However the switchable folding circuit can reach a corresponding high folding factor.

According to another exemplary embodiment of the present invention, an analog-to-digital converter (ADC) is provided comprising a switchable folding circuit having the above-mentioned features.

Using a switchable folding circuit in an analog-to-digital converter may increase the speed of converting an analog signal into a digital value or digital signal and may decreases the power consumption of the ADC. Since a switchable folding circuit may provide a positive power consumption balance, the power consumption balance of the ADC might be improved.

According to a further exemplary embodiment of the present invention a method of operating a switchable folding circuit is provided. The method comprises the steps of receiving an input signal at an input terminal. It further comprises selectively switching the switching units so as to bring, in a part of the circuit stages, a path of the differential pair, the current source and the switching unit in electrically conductive state. Thus, providing an output signal at the output terminal. The output signal at the output terminal is representative for the binary value of an analog signal, or for a part of the binary value. In the latter case the value of the output is further processed using a similar analog-to-digital conversion methods.

The switching scheme of the switching units may be such that, at a time, a part of the switches are open and another part of the switches are closed.

According to another aspect of the present invention a switchable folding circuit is provided, wherein the switching unit is adapted to be closed if a primary signal or if an input signal is in a predetermined interval, which interval corresponds to the switching unit. Since a switchable folding circuit may comprises a plurality of circuit stages and therefore comprises a plurality of switching units, the predetermined interval may differ for each of the switching units.

Using switching units, which are associated with a predetermined interval may allow to detect, if a primary signal falls in an interval. Depending on the interval, in which the value of the analog primary signal is in, the relevant or corresponding switching unit may be closed. Closing the switching unit means that the switching unit is activated. In other words, closing, switching on, activating or triggering the switching unit may mean that a current which is blocked by an open switching unit, may flow and may supply a corresponding circuit stage or differential pair with power. Thus, the corresponding circuit stage is activated.

However, if the switching unit may be closed or may have a non active status, a current may be blocked by the switching unit and the corresponding circuit stage or differential pair which is connected via the switching unit to a current source may be deactivated or may be down. A circuit stage, which is down does not consume power or may have at least a reduced power-consumption.

According to another aspect of the present invention, a switchable folding circuit is provided wherein each interval is predetermined around a set reference value. Selectively switching the switching units on or off may help to generate large output signals. In other words, the amplification of the output signal is increased. The detection of a signal, which has a large amplification may be accurate.

According to another aspect of the present invention, a switchable folding circuit is provided wherein the output signal of the differential pair is adapted in such a way that the output signal may be linear or may be approximately linear if the primary signal varies in the predetermined interval assigned to the differential pair. A linear output signal may provide folds. Such a folded signal may be used for a binary representation of an analog primary signal.

By using inversely connected circuit stages, the primary signal may be converted into a linear signal or an approximately linear signal. The linear signal may be monotonically increasing or decreasing in a corresponding interval. Combining such a linear increasing signal or such a linear decreasing signal results in folding signals, which may have a triangular signal form against an input signal.

A primary signal may be an analog signal, e.g. a voltage, which may be digitized. If the primary signal varies in a range or interval it may be compared to reference levels. Around each of said reference levels there may be an interval defined. These intervals may be limited by borders.

If the input signal falls inside the border of a predetermined interval a predetermined switching unit is activated in order to select a differential pair, which differential pair is associated with the relevant interval or reference value. Thus, in dependency of the reference value, a certain part or section of a primary signal can be extracted or transformed in a channel. This part of the signal then may be converted in another signal. The section of the primary signal may be adapted and may be distributed to a predetermined circuit stage of the switchable folding circuit.

According to another aspect of the present invention, the switching unit comprises a current mirror. Using a current mirror in or in connection with a switching unit may provide a switching unit which does not have a switch in a signal path. A current mirror may allow to realise a switchable folding circuit on an integrated circuit.

According to another aspect of the present invention the switching unit and the current source of at least one of the plurality of circuit stages are formed as a common member.

In this regard a “common” member may particularly denote that the switching unit and the current source are implemented as a single component. For instance the switching unit is implemented as a controlled current source, wherein the source itself is controllably turned on and off. Thus, a switching element in the biasing or signal path, which switch switches only between an on- or off state, may be avoided.

According to another aspect of the present invention, in each of the circuit stages of the switchable folding circuit, the differential pair is connected to the current source via the switching unit.

Using a switch or switching unit directly connected to the current source may allow to separate the current source from the differential pair of a circuit stage.

According to a further aspect of the present invention, a switchable folding circuit is provided wherein the switchable folding circuit is adapted as an integrated circuit. The circuit according to embodiments may be realised as a conventionally wired solution or as a monolithically integrated circuit. In the latter case, the integrated circuit may be formed in semiconductor technology, for instance in silicon technology on the basis of a III-V-semiconductor like gallium arsenide. The circuit may be formed in CMOS or bipolar technology.

According to another aspect of the present invention the switchable folding circuit is provided wherein the input terminal is adapted as an input terminal pair, i.e. having two or more inputs.

A pair of input terminals may allow to supply a differential pair with inverted or redundant input signals. In other words, a differential pair may comprises two branches for a current. By providing each branch with an inverted signal the routing of a current through the branches of a differential pair may be controlled in such a way that a predetermined voltage can be generated as an output signal, wherein the output signal corresponds to a binary representation of the input signal.

According to another aspect of the present invention the output terminal is adapted as an output terminal pair, i.e. having two or more outputs. Similar as using a pair of input terminals a pair of output terminals may provide different representations of an output signal. It may be possible to provide a positive or negative output signal.

In other words a positive and negative output signal represent the same output signal in a different format or as redundant source of information. It is possible that the negative output signal is the inverted representation of the positive output signal. The positive and negative output signal may also be symmetrical.

According to a further aspect of the present invention an ADC is provided comprising a pre-processing unit wherein the pre-processing unit is adapted to receive a primary signal and wherein the pre-processing unit is adapted to convert the primary signal into an input signal for an assigned differential pair. The switching unit of the switching folding circuit may be adapted to be closed if the primary signal is in a predetermined interval which interval corresponds to the switching unit and wherein the predetermined interval differs for each of the switching units of the plurality of circuit stages.

In order to distribute a range or section of a primary signal to the relevant circuit stage of a switchable folding circuit, the pre-processing unit can be used. The pre-processing unit may also serve for other purposes, like pre-amplifying a signal, etc.

According to another aspect of the present invention, an ADC is provided wherein the ADC further comprises a binary decoding unit wherein the binary decoding unit may be adapted to receive the output signal of a circuit stage and wherein the binary decoding unit is adapted to convert the output signal into a binary signal.

Since the output signal of a switchable folding circuit may be a non-binary representation of a primary signal, a binary decoding unit may convert the output of a switchable folding circuit into a binary signal. The binary signal may be the binary representation of the primary signal.

It may be seen as a gist of an exemplary embodiment of the present invention that an analog primary signal can be divided into sub-signals or sections. The sub-signals may be the result of the comparison of the primary analog signal with reference values. These sub-signals of the primary signal may be distributed to certain predetermined switchable folding circuits. It may be sufficient that only the relevant circuit stage has to be activated to process the primary signal.

In other words, a continuous signal, which may be a signal varying (increasing or decreasing) in time, may be divided into sub-ranges or sub-intervals and the parts of the primary signal may be distributed to circuit stages of the switchable folding circuit. The circuit stages may be adapted to the evaluation of the signal in the corresponding interval.

For instance, only the corresponding circuit stage is switched on for the evaluation of the signal in order to reduce power consumption of an integrated circuit and to increase an amplification of a switchable folding circuit. The sub-divided signals may be converted by a binary decoding unit to provide a binary representation of the actual primary analog signal.

These and other aspects of the present invention will become apparent from and elucidated with references to the embodiments described hereinafter.

Exemplary embodiments of the present invention will be described in the following, with reference to the following drawings:

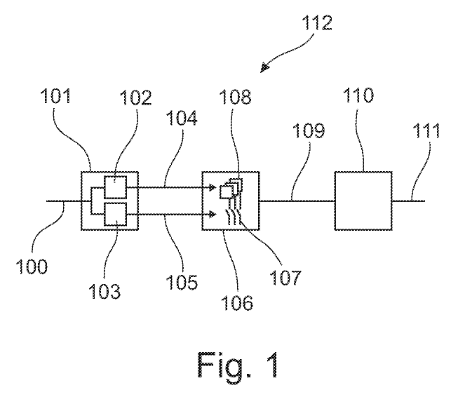

FIG. 1 shows a block diagram of an ADC according to an exemplary embodiment of the present invention;

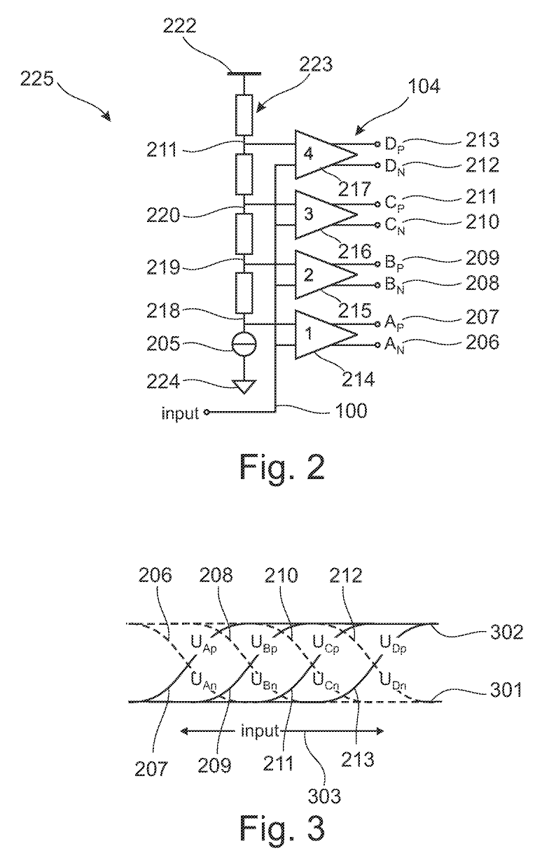

FIG. 2 shows a block diagram of a flash ADC front end;

FIG. 3 shows an output signal of the flash ADC front end;

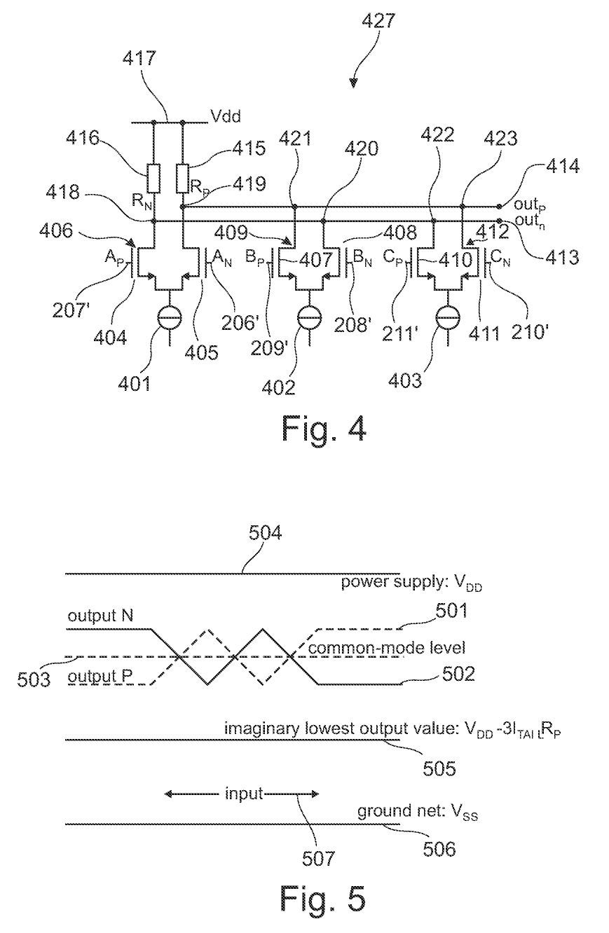

FIG. 4 shows a parallel folding circuit;

FIG. 5 shows an output signal of the parallel folding circuit;

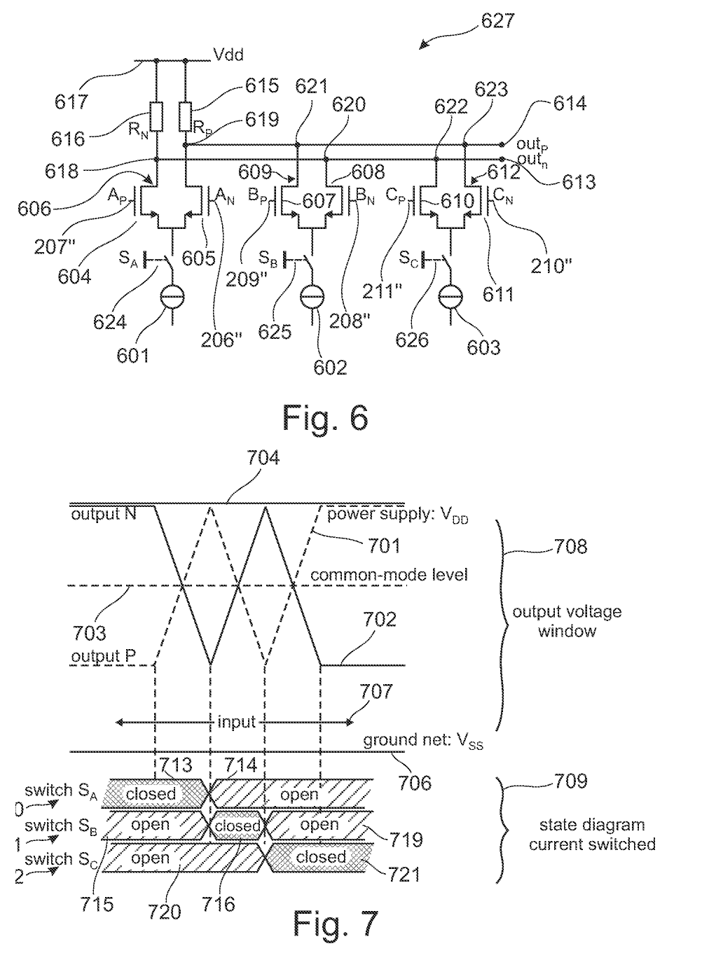

FIG. 6 shows a switchable folding cell with switching units according to an exemplary embodiment of the present invention;

FIG. 7 shows an output signal of the switchable folding cell with switching units according to an exemplary embodiment of the present invention;

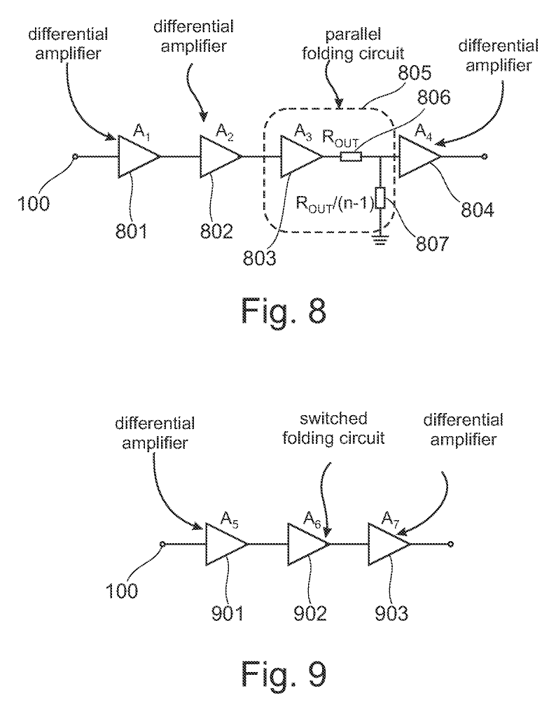

FIG. 8 shows a simplified small signal and equivalent circuit for a parallel folding;

FIG. 9 shows a simplified small signal and equivalent circuit for a switched folding circuit according to an exemplary embodiment of the present invention; and

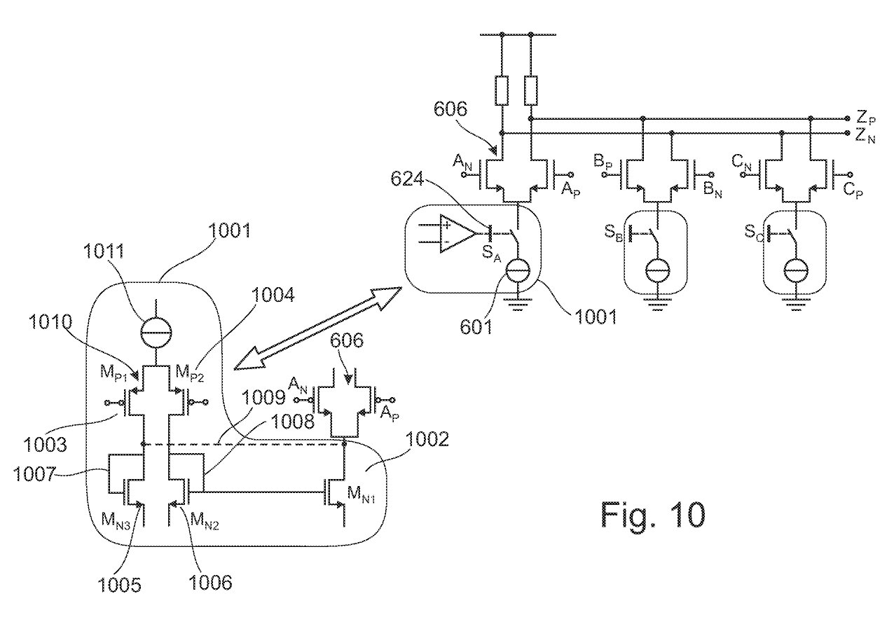

FIG. 10 shows a switching unit according to an exemplary embodiment of the present invention.

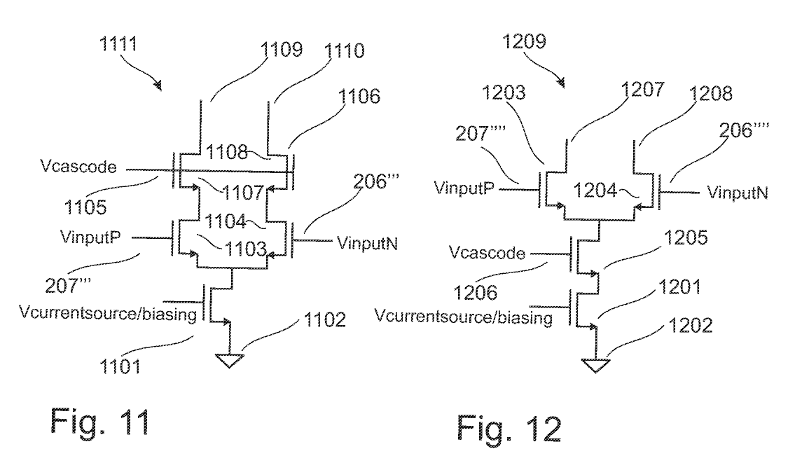

FIG. 11 shows a circuit stage according to an exemplary embodiment of the present invention.

FIG. 12 shows an other circuit stage according to an exemplary embodiment of the present invention.

The illustration in the drawing is schematically. In different drawings, similar or identical elements are provided with the same reference signs.

FIG. 1 shows a block diagram of an ADC according to an exemplary embodiment of the present invention. The ADC 112 comprises a pre-processing unit 101, a switchable folding circuit 106 and a binary decoding unit 110. The terms “switchable folding circuit” and “switchable folding cell” are used equivalent in the content of this text.

A primary signal 100 is provided to the pre-processing unit 101 at the input terminal of the pre-processing unit 101. The primary signal 100 is distributed in the pre-processing unit 101 to a quantifier 102 and a switch control unit 103. The quantifier 102 selects in accordance to a level of the primary signal an input terminal 104 of a relevant differential pair 108 of the switchable folding circuit 106.

The quantifier 102 converts the primary signal 100 on the input terminal of the quantifier 102 into a format, which can be used or processed by the differential pairs 108. For example, the primary signal may be converted into a positive or negative representation of the primary signal 100 at the input terminal. The positive and negative signals may be symmetrical signals or inverse signals.

The switch control unit 103 is adapted to analyze the primary signal 100. According to an interval in which the primary signal lies, the switch control unit 103 provides a switching signal for a corresponding switching unit 107. This control signal is adapted to trigger a corresponding switching unit 107 The switching signal, which triggers the corresponding switching unit 107 is distributed by terminal 105.

The switchable folding circuit 106 provides on its output terminal an output signal on terminal 109. The output signal is routed to the binary decoding unit 110. The binary decoding unit 110 is adapted to convert the signal at terminal 109 into a binary signal, which binary signal will be provided at terminal 111. The binary signal at the terminal 111 is representative for the analog primary signal 100 at the input terminal of the pre-processing unit 101. Furthermore, instead of routing terminal 109 to binary decoding unit 110, another further refinement of the signals may be included. In this case, another folding or switchable folding unit 106 is positioned between the current switchable folding cell 106 and the binary encoder 110.

FIG. 2 shows a block diagram of a flash ADC front end. A straightforward method to convert an analog signal to digital data is to compare the analog input continuously with a set of predefined reference voltages 218, 219, 220 and 221. A set of resistors 223 and a current source 205 define the reference voltages 218, 219, 220, 221, whereas a number of comparators (not drawn in FIG. 2) preceded by the amplifiers 214, 215, 216 and 217 quantify the value of the input signal 100 or primary signal 100. The set of resistors 223 is positioned between a first end of the current source 224 and the reference potential 222. A second end of the current source 205 is connected to a ground potential 224, which is an other reference potential. Another embodiment may have positioned the comperators or amplifiers 214, 215, 216 and 216 between a higher reference voltage 222 and a lower reference voltage 224. The current source 205 or the set of resistors 223 is not the only possibility for providing the reference voltage.

Although the number of amplifiers in the analog pre-processing unit 225 of a flash ADC can be varied, the number of comparators is usually equal to 2^{bits}−1. The term “bits” denotes the number of bits that should be used for the digitalisation of an analog primary signal. If for example an input signal at terminal 100 with 4 bit has to be quantified, 15 comparators are implemented.

By using folding circuits, the number of comparators in a flash ADC can be reduced. The folding circuit depicts a set of comparators multiple times on the analog input range of an ADC. In other words, the input signals selectively generate a signal in a corresponding comparator. Such a comparator performs the calculation of Vref−Vin and −Vref+Vin, wherein Vref is the corresponding reference value, e.g. a voltage 218, 219, 220, 221, with 0<Vref. Vref 218 is determined by the electrical potential provided at reference point 224, the current source 205 and the reference ladder 223. Therefore Vref 218 may be above zero. Vin is the primary signal 100 at terminal input. Several variations of circuits exist to execute this folding operation.

The pre-amplifier 214, 215, 216 and 217 are connected to the reference voltages 218, 219, 220 and 221 and to the primary signal 100. Each of the pre-amplifiers 214, 215, 216 and 217 provides two output signals at the output terminal 206, 207, 208, 209, 210, 211, 212, 213 of the respective pre-amplifier. One of the output signals is a negative output signal 206, 208, 210 and 212 calculated according to the formula Vref−Vin and the other one is a positive output signal 207, 209, 211 and 213 calculated according to the formula −Vref+Vin. The signals 206, 207, 208, 209, 210, 211, 212, 213 are provided at corresponding output terminals of the pre-amplifiers 214, 215, 216 and 217.

FIG. 3 shows output signals 206, 207, 208, 209, 210, 211, 212, 213 of the flash ADC front end 225 or quantifier 225. FIG. 3 shows a diagram of the output signals 206, 207, 208, 209, 210, 211, 212, 213 of the pre-amplifier 214, 215, 216 and 217. The input signal or primary signal 303, 100 of the input terminal of the pre-processing unit 101 is divided into predetermined intervals.

For example, the output signal 206 of pre-amplifier 214, which signal is illustrated as a dotted line in FIG. 3, changes between a maximum value 302 and a minimum value 301. The signal has an S-shaped form over a predefined interval, which interval is predefined around the reference value 218. The left border of the interval is in the area where the signal 206 is equal to the maximum value 302. The right border of the interval is where the signal 206 is equal to the minimum value 301. The borders for the corresponding intervals for signals 208, 210, 212 are defined accordingly.

The solid line 207 shows the characteristic of the symmetrical or inverse signal 207 to the output signal 206. In the middle of the interval around the reference value 218, the negative 206 and positive 207 output signal of pre-amplifier 214 are crossing another. As an alternative exemplary embodiment the node 211 may be connected to a positive voltage 222 and the node 218 may be connected to a negative voltage 224. Then the different reference voltages do not have to be generated by a resistance ladder 223, which is connected to an upper supply voltage 222 and a current source 205. There are many other embodiments of how the different reference voltages may be provided.

An increasing input signal 303, 100 in FIG. 3 is depicted from the left to the right. While the negative signal 206 is decreasing with increasing values of the input signal 303, the positive signal 207 is increasing accordingly.

The signal pair 206, 207 represents the output signal of pre-amplifier 214 in the predetermined interval around reference value 218. Each of the signal pairs 209 and 208, 211 and 210, 213 and 212, represent the output signal of the pre-amplifier 215, 216, 217 in the predetermined interval around reference values 219, 220, 221 accordingly.

FIG. 4 shows a parallel folding circuit. Several differential pairs 406, 409, 412, are connected to a resistive load 415, 416. Each of these pairs 406, 409, 412 is inversely connected in comparison with its neighbour. The resistive loads 415, 416 provide a voltage difference depending on the current flow through the resistive loads 415, 416. Therefore this voltage relates to the amplification. Instead of resistive loads different components, e.g. a current source can be used or other structures can be used providing a voltage difference.

Inversely connecting means that the output terminals of the differential pairs are alternatingly connected together. The differential pair 406 is now exemplarily described for the differential pairs 409 and 412.

The differential pair 406 comprises a first transistor 404 and a second transistor 405. The first transistor 404 provides a first input terminal 207′, wherein the first input 207′ of the differential pair 406 is connectable to the corresponding output terminal of pre-amplifier 214 in FIG. 2, which terminal provides the corresponding output signal 207.

The transistor 405 provides an input terminal 206′, which is connectable to the corresponding output terminal of pre-amplifier 214 in FIG. 2, which terminal provides the corresponding output signal 206. The differential pair 406 is the corresponding differential pair, which changes the states of the transistors 404, 405 for input signals corresponding to signals which are in an interval around reference level 218.

The input terminals 206′, 207′, 208′, 209′ 210′, 211′ and 212′ are adapted to receive the relevant signals 206, 207, 208, 209, 210, 211 and 212.

The sources of the transistors 404, 405 of the differential pair 406 are connected together. The connected sources belonging to transistors 404, 405 of the differential pair 406 are also connected to the current source 401.

The differential pair 406 provides a negative output terminal 418 and a positive output terminal 419. The differential pair 406 provides at its negative output 418 a first output signal, and on its positive output 419 a second output signal. The output terminals 418 and 419 are inversely connected to the output terminals 421 and 420 of differential pair 409 and the output signals 422 and 423 of the differential pair 412.

The aggregation of the different output signals of the neighboured differential pairs 406, 409 and 412 are provided at the positive output terminal 414 and the negative output terminal 413. The signal provided at the outputs 413, 414 depends on the input signals 206, 207, 208, 209, 210, 211 of the differential pairs. According to the input signals, current from the current sources 401, 402 und 403 is routed through the differential pairs 406, 409, 412 and through the resistors 415, 416, wherein a corresponding voltage is generated by current flowing through the resistor 415, 416.

FIG. 5 shows an output signal of the parallel folding circuit. As shown in FIG. 5, by inversely connecting the differential pairs 406, 409 and 412 in comparison with its neighbours, a folded signal originates from the linear input value. The type of folding structure shown in FIG. 4 will be referred to as “parallel folding circuit”. The amplification of the array is reduced with the folding factor of the circuit. The folding factor expresses how many times the comparator array is depicted on the input range, or how many parallel differential pairs 406, 409, 412 are present in a circuit. In the case shown in FIG. 4 the folding factor is 3.

It is believed that the low amplification can be explained as follows: imagine three differential pairs, which are not interconnected. The output voltage of such a pair can vary from V_{DD}−Iₜₐᵢₗ*R_{load} uP to V_{DD} 504. V_{DD} is the supply voltage provided at line 417. If the outputs are connected to each other, the newly merged load resistor will be reduced with a factor 3 while the tail currents will remain the same. Thus, R_{P}=R_{N}=R_{load}/3.

In other words, the output terminals 419, 421 and 423 are connected together with resistor 415. The maximum current through each of these outputs is Iₜₐᵢₗ. However, as the outputs are inversely connected, the output voltage can vary between V_{DD}−Iₜₐᵢₗ*R_{P} and V_{DD}−2Iₜₐᵢₗ*R_{P} for any input voltage. As the resistor 415 is only one third of the resistor value in the imagined differential pair the voltage now varies between V_{DD}−(⅔)*Iₜₐᵢₗ*R_{load} upto V_{DD}−(⅓)*Iₜₐᵢₗ*R_{load}. Compared with the output of a single differential pair this is a reduction of factor 3 compared to a single differential pair V_{DD}−Iₜₐᵢₗ*R_{load}.

The resulting output voltages of the folding circuit have a common mode value 503 of U_{out, commonmode}=V_{DD}− 3/2 (Iₜₐᵢₗ*R_{P}) 505 while the formula for the voltage swing remains U_{out, differential}=Iₜₐᵢₗ*R_{P}. But as the connected load resistor 415 is one-third of the value of the imagined differential pair, the voltage swing is actually also divided by 3.

In general, the original amplification of a differential pair is reduced by the number of folding operations. As also the original amplification of the differential pair 406, 409, 412 is mostly chosen rather low (for instance 3-10 times) to achieve a high bandwidth the amplification of the total folding circuit is limited to unity or somewhat more.

The parallel folding circuit illustrated in FIG. 4 is constituted by three pairs of transistors 404, 405, 407, 408 and 410, 411, each pair having a current source 401, 402, 403, providing for a constant current Iₜₐᵢₗ, and resistors 416 and 415 connecting the transistors to a power supply V_{DD} 417. The resistors 416 and 415 form a resistive load R_{load}. Each of the current sources 401, 402, 403 is supposed to provide for a constant current, while further the resistors 416 and 415 are equal Rn=Rp.

Input signals 207, 209 and 211 and inverted input signals 206, 208 and 210 respectively are supplied to the base or gate 206′, 207′, 208′, 209′, 210′, 211′ of the pairs of transistors 404, 405, 407, 408, 410, 411. These input signals are composed of an input signal 100 and reference signals 218, 219 and 220. When the folding circuit is applied in an analog-to-digital converter, the input signal 100 is considered to be the signal to be converted.

When the input signal or primary signal 100 is zero, the transistors 404, 407, 410 are blocked since they have a negative voltage at their gate and the current routing is via transistors 405, 411 and resistor 415 and the current routings via transistor 408 and resistor 416 provide a “low” voltage on the output Outₚ 414, i.e. a voltage V_{DD}−Iₜₐᵢₗ*R_{load}, wherein Iₜₐᵢₗ is the current through the current sources 401, 402 and 403 and R_{load}=Rₙ=Rₚ 416, 415, and “high” voltage on the output Outₙ 413, i.e. a voltage V_{DD}−Iₜₐᵢₗ*R_{load}.

When the input signal 100 increases this situation remains unaltered until the input voltage 100 comes in a certain range or interval around the reference value 218.

Then, an increasing current through the transistor 404 and a decreasing current through transistor 405 is obtained until transistor 405 is blocked and the current routings via transistor 404, transistor 408 and resistor 416, and the current routing via transistor 411 and resistor 415 provide said “low” voltage on the output Outₙ 413 and said “high” voltage on the output Outₚ 414, until the input signal is further increased and comes in a range or interval around the reference value 219 which range is supposed to be equal and in succession to the above range around reference value 218 and an increasing current through transistor 407 and a decreasing current through transistor 408 is obtained until transistor 408 is blocked and the current routing via transistor 404 and resistor 416 and the current routings via transistor 407, transistor 411 and resistor 415 provides said “high” voltage on the output Outₙ 413 and said “low” voltage on the output Outₚ 414.

When the input signal is further increased and comes in a range around the reference value 220, which range again is supposed to be equal and in succession to the above ranges, an increasing current through transistor 410 and a decreasing current through transistor 411 is obtained until transistor 411 is blocked and current routing is via transistor 404, transistor 410 and resistor 416 and a current routing via transistor 407 and resistor 415 provides said “low” voltage on the output Outₙ 413 and said “high” voltage on the output Outₚ 414.

FIG. 5 shows the voltage values 501, 502 on the outputs Outₚ 414 and Outₙ 413 as a function of the input signal 507, 100, which represents a primary signal at the input terminal of pre-processing unit 101. It can be seen that in the ranges around the reference voltages, that is in the range of the crossing of the solid line 502 and the dotted line 501, the voltage 501 on the outputs Outₚ 414, and the voltage 502 on the output Outₙ 413 respectively provide a folding with a folding factor 3. The resulting output voltages of the folding cell have a common value of V_{DD}− 3/2 Iₜₐᵢₗ*R_{load} and a voltage swing of Iₜₐᵢₗ*R_{load}.

Similar to FIG. 3, the input voltage 507, 100 is illustrated in FIG. 5 as increasing from the left to the right side of the picture. As can be seen from FIG. 5, the folding of the output signals 501 and 502, respectively, is performed in the range in that the input voltage 507 is present. The borders of this range are marked by the arrows of line 507.

The theoretical highest achievable output voltage is indicated by line 504. The value of this maximum equals to the supply voltage V_{DD}. The theoretical minimum value for the output signals is indicated by line 505, which represents a value of V_{DD}−3*(Iₜₐᵢₗ*R_{P}).

The ground net voltage V_{SS} is illustrated as line 506. The ground net voltage is provided as reference potential. It may be a reference point to connect a current source 401, 402, 403.

FIG. 6 depicts a circuit to generate folding signals according to an exemplary embodiment of the invention.

The switchable folding circuit 106 shown in FIG. 1 may be realised in a manner as shown in FIG. 6.

FIG. 6 shows three differential pairs 606, 609 and 612. Each differential pair 606, 609, 612 comprises a first transistor 604, 607, 610 and a second transistor 605, 608, 611. Each transistor comprises a gate 206″, 207″, 208″, 209″, 210″, 211″ wherein each gate is adapted to receive a corresponding input signal A_{P}, A_{N}, B_{P}, B_{N}, C_{P}, C_{N}. An input signal for the gate 206″, 207″, 208″, 209″, 210″, 211″, 212″ could be a corresponding output signal 206, 207, 208, 209, 210, 211, 212 of a pre-amplifier (for example in a similar manner as illustrated in FIG. 2).

Each differential pair 606, 609, 612 is connected to a current source 601, 602, 603 via switches (for instance transistor switches) or switching units S_{A} 624, S_{B} 625 and S_{C} 626. Selectively switching them on and off will help generating larger output signals. A short description of how it works will be provided in the following:

A switching unit is a control element for activating a differential pair. In other words, in order to supply a differential pair with current, a corresponding switching unit is activated. A switching unit may be activated if a switch is closed.

If the input signal 100 is low or near the reference level 218 of differential pair A 606, switches S_{B} 625 and S_{C} 626 are open and only switch S_{A} 624 is closed. By doing so, the circuit is functioning equivalent to a differential pair, with some non-conducting transistors as extra capacitive load. Therefore the voltage amplification is also equivalent to a single differential pair.

If the input signal is near the reference level 219 of pair B, switch S_{A} 624 will be opened and S_{B} 625 will be closed. Meanwhile switch S_{C} 626 stays opened.

If the input signal 100 is near the reference level 220 of pair C, switch S_{B} 625 will be opened and S_{C} 626 will be closed. Meanwhile switch S_{A} 624 stays opened.

In other words, different differential pairs are employed to analyse a signal, which signal has to be digitised. In order to select the differential pair corresponding to a certain interval of an input or primary signal 100 a pre-processing unit 101 is employed. The pre-processing unit 101 is not shown in FIG. 6. One example for a pre-processing unit 101 or quantifier 101 is shown in FIG. 2.

A switch control unit 103, also not shown in FIG. 6, provides control signals to trigger the switching unit 624, 625, 626, which receives a signal from the pre-processing unit 101. Since exactly one switching unit 624, 625, 626 is activated, the other switching units are de-activated. Thus, no current flows through the de-activated switching units 624, 625, 626. Since a circuit stage comprises a differential pair 606, 609, 612, a current source 601, 602, 603, and a switching unit 624, 625, 626, a de-activated switching unit results in a de-activated circuit stage. Therefore the power consumption is limited to the power consumption of one differential pair 606, 609, 612, in particular to the power consumption of one circuit stage.

The various states of the switches 624, 625, 626 as function of the input voltage 100 is depicted in FIG. 7. Parallel folded circuits with a resistive load as shown in FIG. 5 suffer from attenuation of the output signal 413, 414, whereas the attenuation is equal to the fold factor.

The amplification of a differential pair is equal to the transistors' transconductance times the output impedance or load resistor. Similar to the parallel folding circuit depicted in FIG. 4, the equivalent load resistor is reduced three times, while always at most one differential pair influences the output, while the other differential pairs are saturated, the total amplification is reduced three times with respect to a single differential pair. If therefore, e.g., a parallel folding circuit as depicted in FIG. 4 consists of three parallel differential pairs 406, 409, 412 with an original voltage amplification of four, than the amplification of the constructed folding amplifier is reduced to 4/3, which is close to unity.

Switched folding as shown in FIG. 6 applies various folding factors, with almost no amplitude reduction. If a switched folding circuit 627 is constructed with the same components of the earlier mentioned differential pair, the amplification of the whole switchable folding circuit remains equal to approximately 4, which is the amplification of a single differential pair. The effective amplification can be somewhat reduced if the “closed-state” of switches 624, 625, 626 overlap. As switches 624, 625, 626 may be constructed by transistors, the transition of “on” to “off” can be less rigorous in practice.

Less strong matching requirements and less sensitivity to substrate noise of the succeeding circuits may also be an advantage of a switchable folding circuit. As always only one current source and one differential pair is active, only the mismatch of these components contribute to the output error. In case of the parallel folding circuit e.g. the mismatch of all current sources 401, 402 and 403 contribute to the output error. The power consumption of the succeeding stage of a switchable folding circuit can be much lower, as larger analog signals are easier to convert to digital values.

In the following, higher power-efficiency at same speed will be described.

In case of 3-times switched folding, only one tail current source 601, 602, 603 is present or active, while a parallel folding circuit needs three tail current sources 401, 402, 403 to generate the same folding factor.

In other words, in order to prevent a current flowing through a circuit stage, which is corresponding to an interval of the input signal 100, which is not relevant for the digitalisation of the actual input voltage, this part of the switchable folding circuit 627 is switched off. Therefore, this part is de-activated and the power consumption of this part is reduced. The processing of the input signal 100 is only performed in a certain part of the switched folding circuit 627. Therefore, it does not effect the functionality of the switchable folding circuit 627 if the parts of the circuit 627, which parts are not used, are switched off.

The number of folds in the output signal of a switchable folding circuit 627 is equal to the number of folds in the output signal of the parallel folding. Only one current source 601, 602, 603 is active at the same time, when using a switchable folding circuit.

Also a 7-times cross coupled folding circuit, as described in WO 2005/01125 A1, may have one active current source. However the large number of interconnected drain and gate capacitances may restrict such a large power advantage. Also the shorter path between input of the complete ADC, which comprises a switchable folding circuit, and the inputs of the comparators therein may reduce the speed requirement of the intermediate circuitries, wherein the circuitries also comprise the folding circuit and thus total power consumption of the ADC can be reduced.

FIG. 7 shows a diagram of the output signals 614, 613 of a switchable folding cell 627 according to an exemplary embodiment of the present invention.

An input signal 100 is represented as line 707. The left end of line 707 represents the minimum value of the input signal 707, 100. Following the line 707 from the left end to the right end means increasing the input voltage 707, 100. The maximum input voltage 100 is reached at the right end of line 707.

Increasing the input signal 100, 707 from the minimum value to the maximum value results in a folded output signal 702 and an inverse folded output signal 701. These signals are the signals provided at the outputs 613, 614 of the switchable folding cell 627. The positive output terminal 614 provides the positive output signal 701, and the negative output terminal 615 provides the negative output signal 702.

The positive output signal 701 is generated by accumulating the signals at the output terminals 619, 621, 623 of the differential pairs 606, 609, 612 of the switchable folding cell 627.

The negative output signal 702 is generated by accumulating the signals at the output terminals 618, 620, 622 of the differential pairs 606, 609, 612 of the switchable folding cell 627.

In FIG. 7 the state diagram 709 of a current switched circuit is shown. In this state diagram the state diagram 710, 711, 712 for different switching units 601, 602, 603 are illustrated. The states relate to the level of the input signal 100, 707. The information about the actual state of the input signal can be provided by a switch control circuit 103.

The states of the state diagram 710, 711, 712 divide the input voltage 707 in three sections. In the first section 713, the first switching unit 624 is activated. Therefore, the first switching unit 624 is closed 713, whereas the second switching-unit 625 and the third switching unit 626 are open 715, 720.

In the second section 716 the first switching-unit 624 and the third switching-unit 626 are open 714, 720, whereas the second switching-unit 625 is closed. Thus, only current of the second current source 602 is routed through the second differential pair 609 and through the resistors 616 and 615.

In the third section 721 the first switching-unit 624 and the second switching-unit 625 are open 714, 719, whereas the third switching-unit 626 is closed.

Since only one differential pair 606, 609, 612 is active, current is only provided through this active differential pair. Therefore the current through the resistor 616, 615 is only provided from one single current source. The voltage across the resistors R_{N} 616 and R_{P} 615 varies between V_{DD} and V_{DD}−R_{load}*Iₜₐᵢₗ, wherein R_{load}=R_{N}=R_{P} and Iₜₐᵢₗ relates to the current through the current sources 601, 602, 603.

This variation of the output voltage can be seen in the output voltage window 708 in FIG. 7. The characteristics 701 and 702 show the variation of the signals provided at the common outputs 614, 613 of the switchable folding circuit 627. In FIG. 7 the signals are represented as voltage characteristics 701, 702, which are symmetrical in relation to the common-mode level 703. The characteristics 701, 702 are composed of sectionally increasing and decreasing linear characteristics, which build the folded output signals 701, 702 for an input signal 100 at the input of an ADC 112. The positive output signal 701 and the negative output signal 702 subtend if the input voltage 100, 707 reaches corresponding reference levels 218, 219, 220, 221. These intercept points are also subtended by the common-mode level line 703.

The folded signals 701, 702 discussed above are representative for a binary depiction of the actual analog input signal 100, 707. The binary representation of the input signal is generated in a binary decoding unit 110.

A performance analysis can be performed by using a fixed “mismatch budget”. The effective mismatch of all contributors can be viewed as a single error voltage source present at the input. To estimate the power reduction, which could be gained by application of embodiments of the invention a few assumptions will be made to simplify calculations. Thereafter, the power reduction will be estimated incorporating the relaxed static requirements which are allowed in this implementation and the relaxed dynamic requirements.

The static requirements of the circuit refer to the summation of all non-idealities and non-equalities between devices, which are intentionally equal in a static input signal. E.g. the transistors 604, 605 are intentionally equal but can in practice deviate in transconductance.

The dynamic requirements of the circuit refer to the extra deviation of the output voltage, above the static error, caused by the limited processing speed of the circuitry if a continuous changing input signal is applied.

Assumption one: The allowed offset budget of zero crossings inside the ADC is effectively distributed equally over the various amplifiers folding stages and comparators. Thus, each next folding stage or comparator will increase the referred input mismatch with more or less the same magnitude. Typically the transistors in the first stage are chosen large, and thus have a lower mismatch.

As the signals are amplified after the first stage, the influence of the succeeding stages is less severe. The second stage can therefore be chosen smaller, as the mismatch of this circuit will have a reduced effect on the referred input mismatch. To increase overall bandwidth, the succeeding stages are chosen to be much smaller and end up with a much higher absolute offset. In practical cases, the amplification is more or less equal to the increase in offset of the succeeding amplifier. Therefore, the offset contribution of each of them is more or less equal.

Assumption two: The amplification of the parallel folding stage 427 approaches for example 4/3 which is close to unity, as described above. As an amplification of three of a separate differential pair is a practical value, a 3-times parallel folding stage 427 designed with the same transistors yields no amplification or an amplification of unity at all.

In contrast, the switched folding stage 627 will amplify the signal 3 times, as the load resistor is equal to the load of the separate differential amplifier, as described above.

In other words, resistors 615 and 616 of the switched folding circuit 627 conduct the current of one tail current source, while the resistors 415 and 416 of a parallel folding circuit 427 conduct the sum of all three tail current sources. To achieve the same common mode level 703, 503 in both cases, the resistors 615 and 616 may be chosen three times larger.

Using similar transconductances of the transistors in a parallel folding circuit 427 and a switchable folding circuit 627, the switchable folding circuit has a three times higher amplification.

Assumption three: The distortion of the switched folding stage 627 is equal to the distortion of the parallel folding stage 427. This can be derived from the origin of the distortion. In both cases, the parallel 427 and the switched folding circuit 627, the third and other harmonics are generated by the non-linear MOS curve of the input transistors. As almost no changes are made in the dimensions of the devices and their voltage levels, this assumption is valid.

For very small variations of the input signal any flash or folding ADC looks like a concatenation of amplifiers, see FIG. 8. The amplification of the chain of amplifiers is, logically the multiplication of their individual voltage amplification AUₓ, with incorporation of the attenuation of a parallel folded circuit:

$${A}_{U , total} = {A}_{U , A 1} \cdot {A}_{U , A 2} \cdot {A}_{U , A 3} \cdot \frac{{R}_{out}}{{R}_{fold}} \cdot {A}_{U , A 4} \qquad ( 1 )$$

In this case the first amplifier A1 801 is a normal amplifier circuit, followed by second amplifier A2 802, a parallel folding circuit A3 803 and finally an amplification stage A4 804, which is needed to amplify the signal to accommodate the comparator requirements.

In other words a flash ADC and a parallel folding ADC comprise the same logical stages. For example, they comprise a differential amplifier A1 801, which is adapted to pre-amplify the input signal 100. The pre-amplifier may be a quantifier or a flash ADC front end as depicted in FIG. 2. After this first amplifier a second stage A2 802 provides an additional amplification factor.

The second stage is an amplifier 802. The next stage is the amplification of the parallel folding circuit 427. It provides an amplification A3 and an attenuation through the resistor network, built of the resistor Rₒᵤₜ 806 and R_{fold} 807. R_{fold}=Rₒᵤₜ/(n−1), wherein n is the number of folding stages. Rₒᵤₜ is the resistor placed in the signal path. R_{fold} is the resistor connected to ground level and Rₒᵤₜ. Rₒᵤₜ is also connected to the fourth stage A4 804 of the amplifier stage. Differential amplifier A4 is used as an output-amplifier and to compensate the attenuation added by the resistor network 806, 807.

The amplification is now, in the case of switched folding:

A_{U,total}=A_{U,A5}·A_{U,A6}·A_{U,A7} (2)

In other words. FIG. 9 shows the simplified small signal equivalent circuit for a switched folding circuit according to an exemplary embodiment of the present invention.

FIG. 9 shows 3 amplification stages that are typical for a switchable folding ADC. The first stage A5 901 is a differential amplifier, which pre-amplifies an input signal 100. The pre-amplifier may be a quantifier 102, 225 which selects the intervals for a succeeding switchable folding circuit. Such a quantifier is, for example, depicted in FIG. 2.

At the output of the differential amplifier 901, a switched folding circuit 902 and an amplifier 903 are connected in a series connection. They provide the amplification stage A6 902 and the amplification stage A7 903. Stage, 902 represents the amplification of a switching folding circuit as depicted in FIG. 6. An second input amplifier resembling 802 is not necessary since the amplification of stages A6 902 and A7 903 is high enough.

In any ADC the quantization noise is defined by the number of references levels 218, 219, 220, 221. Added to this type of noise is the noise generated by randomly positioned deviations of the offset. Both types of noise can be summed, assuming they are uncorrelated, according to the following formula:

Uₙₒᵢₛₑ=\sqrt{U²_{quantization}+U²_{offset}} (3)

Uₙₒᵢₛₑ is the voltage of the total noise, U_{quantization} is the voltage of noise caused by the digitization of the analog signal 100. U_{offset} is voltage caused since the characteristics of the components in an ADC are not exactly the same.

Assuming that the quantization noise level of 8-bit ADC is equal to offset induced noise, than the actual ADC performance is 7.5 ENOB (effective number of bits). The offset induced noise itself originates from various offset sources, which can be summed together in a similar way.

The total allowed offset noise can now be viewed as a “mismatch budget”, which sets the maximum offset of the circuitry. Each individual offset source should therefore be smaller in comparison with the budget, especially if there are many offset contributors. For conventional implementation as mentioned before, using four amplifiers in concatenation, the analysis is as follows:

$$\begin{matrix}{U}_{budget}^{2} = {U}_{offset ( A 1 )}^{2} + {U}_{offset ( A 2 )}^{2} + {U}_{offset ( A 3 )}^{2} + {U}_{offset ( A 4 )}^{2} \\ = 4 \cdot {U}_{offset ( A 1 )}^{2} \\ {U}_{offset ( A )} = \frac{1}{2} \cdot {U}_{budget} = 0.5 \cdot {U}_{budget}\end{matrix} \qquad ( 4 )$$

The requirement for each amplifier to fulfil is to have at most half of the offset voltage U_{offset} of the offset budget.

Equation (4) describes the offset balance to a flash ADC or parallel folding circuit as shown in FIG. 8. The same analysis for the implementation of embodiments of the invention, as described before, yields:

$$\begin{matrix}{U}_{budget}^{2} = {U}_{offset ( A 5 )}^{2} + {U}_{offset ( A 6 )}^{2} + {U}_{offset ( A 7 )}^{2} \\ = 3 \cdot {U}_{offset ( A 1 )}^{2} \\ {U}_{offset ( A )} = \frac{1}{\sqrt{3}} \cdot {U}_{budget} \approx 0.57735 \cdot {U}_{budget}\end{matrix} \qquad ( 5 )$$

The requirements for each amplifiers are somewhat relaxed, although not impressive. But as the only way to reduce offset (without using calibration techniques) is to increase area (see Pelgrom M. J. M., Duijnmaijer A. C. J., and Welbers, A. P. G., “Matching properties of MOS transistors” IEEE Journal of Solid-State Circuits vol. 24, 1433-1440, October 1989), the ratio between both number should be squared to give an idea of the reduction of power consumption for a individual amplifier. The resulting power reduction of individual amplifiers thus equals 25%.

In other words, since an ADC comprising a switchable folding circuit has a reduced number of amplifiers, the ADC with a switchable folding circuit has a higher offset budget for individual amplifier and folding circuits. Gaining such an offset budget with an ADC comprising one additional amplifier would mean that the required area on an integrated circuit has to be increased. This increase of the area would result in an increase of power consumption of the circuit.

In the following, the power distribution along the ADC architecture is discussed.

There is also an impact on the topology of the folding ADC. As drawn in FIG. 8 and FIG. 9, the same amplification can be reached using three instead of four amplifiers. For a flash and folding ADC, the first amplifiers, although, low in number, consume the most power, as there linearity and offset requirements are the most demanding. Assuming each stage consumes half of the power of the preceding stage, in case the signals are amplified, a distribution as listed in Table 1 is a valid example.

Amplifier A2 802 consumes half of the power of amplifier A1 801, and amplifier A4 804 half of the power of A3 803. The power consumption of A3 803 is kept equal to A2 802 as the amplification is almost unity (assumption two). This distribution of (allowed) power consumption is similar to the design topology used in Scholtens, P. C. S., Vertregt, M., “A 6b 1.6 GS/s Flash ADC in 0.18 μm CMOS using averaging termination.”, IEEE Journal of Solid-State Circuits, December 2002, vol. 37, no. 12, pp. 1599-1610.

TABLE 1

| | parameters per state | | | | | |
|---|---|---|---|---|---|---|
| | amplifier | A1 | A2 | A3 | A4 | total ADC design |
| | estimated | 400 mW | 200 mW | 200 mW | 100 mW | 900 mW |
| | power | | | | | |
| | consumption | | | | | |
| static | amplifier | A5 | A6 | — | A7 | |
| improvements | | | | | | |
| | possiblepower reduction | ${( \frac{0.5}{0.57735} )}^{2}$ | ${( \frac{0.5}{0.57735} )}^{2}$ | $\begin{matrix}removed \\ \frac{1}{∞} \to 0\end{matrix}$ | ${( \frac{0.5}{0.57735} )}^{2}$ | ${P}_{{invent}_{static}} = 0.583 \cdot {P}_{{prior}_{art}}$ |
| | new power | 300 mW | 150 mW | 0 mW | 75 mW | 525 mW |
| | estimation | | | | | |
| dynamicimprovements | possiblepower reduction | unalteredw 1 | $\sqrt{\frac{2}{3}}$ | | $\sqrt{\frac{2}{3}}$ | $\begin{matrix}{P}_{{invent}_{static}} = 0.537 \cdot {P}_{{prior}_{art}} \\ {P}_{{invent}_{dy samic}} = 0.922 \cdot {P}_{{invent}_{siatin}}\end{matrix}$ |
| | new power | 300 mW | 123 mW | 0 mW | 61 mW | 484 mW |
| | estimation | | | | | |

In the following, reduction of bandwidth for individual amplifiers will be discussed.

A similar reasoning to the mismatch budget can be done for the settling time of the amplifiers. For a concatenation of amplifiers, each with a settling time t_{Ax}, the total settling time can be estimated by:

tₛₑₜₜₗₑ≈\sqrt{t²_{A1}t²_{A2}+ . . . +t²_{An}} (6)

Assume all settling times of all the amplifiers involved are equally in size, as this is the preferred solution for power efficiency, the settling of an individual amplifiers is now a function of the required settling time and the number of amplifiers, called n:

$${t}_{An} \approx \frac{{t}_{settle}}{\sqrt{n}} \qquad ( 7 )$$

If a (distributed) sample-and-hold stage is positioned between the first and second amplifier/folding stage the settling time requirement should be met by the second till third (or fourth) amplifier/folding stage.

As stated in the above-mentioned Table 1, a conventional solution includes three amplifiers, positioned after the sampling stage, which in combination should meet the settling requirement, while embodiments of the invention may reach the same amplification in two stages. The reduction in number of stages relaxes the settling requirement of the individual stages, according to equation (7), which linearly translates to a power reduction of these stages.

This insight allows a further reduction of the estimated power consumption of an implementation of embodiments of the invention, see the above-mentioned Table 1. The power consumption of an ADC implemented according to embodiments of the invention could be realised in 484 mW with equal static and dynamic performance as conventional implementations of 900 mW. This is a reduction in power consumption of 46.2%.

In the following, circuit examples will be mentioned, for instance a switched folding example.

FIG. 10 shows a switching unit according to an exemplary embodiment of the present invention.

Switching a current mirror on and off can be done by modifying the accompanying biasing diode, see FIG. 10. A PMOS differential pair 1010 (MP1 1003 and MP2 1004) directs its current to a NMOS diode (MN2) 1006 of the current source (MN1) 1002 if the appropriate fold is selected. If the voltage range is outside the defined range of this fold, the PMOS pair 1010 directs its current 1011 to a dummy load (MN3) 1005. Eventually the voltage at this node can be used to pull up the tail current node (as connected by the dotted line) 1009.

In other words, FIG. 10 shows an exemplary embodiment, how a switching unit 624 may be realized. A switching control unit, not drawn in FIG. 10, provides a control signal to the input gates of the transistors 1003, 1004. A switching signal is provided, if the input is in a corresponding interval for the corresponding differential pair 606.

If the switching unit shall be switched on, the signal from the switching unit triggers transistor MP2 904. Current from current source 1011 can be directed to the NMOS diode (MN2) 1006 which activates the current source 1002 in form of transistor MN1 1002. Thus, the differential pair 606 is activated. As can be seen in FIG. 10, it is not necessary that a switch is in the path between current source 601, 1002 and differential pair 606.

The dummy 1007 is chosen relatively small to allow a strong increase in voltage, and prevent leakage from the tail current. Transistors can be MOS or bipolar. Differential pair MP1/2 is a Gilbert cell (analog multiplier) if off-on-off sequence is required (like SB in FIG. 7). Cascoded current sources can be used. Resistive output load can be (cross-coupled) transistor/diode (infinite impedance).

FIG. 11 shows a circuit stage according to an exemplary embodiment of the present invention. The source of transistor 1101 is connected with ground potential 1102. Transistor 1101 is used as biasing current source. This current source can be controlled according to a current or a voltage provided at the gate of transistor 1101. The current source 1101 may be controlled by a switch control unit 103 (not shown in FIG. 11). Thus transistor 1101 realizes a current source and a switch in one common member.

The drain terminal of the transistor 1101 is connected to a differential stage, comprising 4 NMOS transistors 1103, 1104, 1105, 1106. Transistors 1103, 1104 are connected as a differential pair similar to the differential pair 606 in FIG. 6. The source terminals of transistors 1103, 1104 are connected together and the source terminals of transistors 1103, 1104 are connected to the drain terminal of transistor 1101. At the input terminals 207″′ and 206 ″′ signals from an output stage of a pre-amplifier (not shown in FIG. 11) are provided.

Instead of being directly connected to output terminals 614, 613 (not shown in FIG. 11) and load resistors 615, 616 (not shown in FIG. 11), the drain terminals of transistors 1103 and 1104 are connected to a further differential pair 1107, 1108. This additional differential pair 1107, 1108 is implemented as a cascode circuit 1107, 1108.

Thus, the differential stage has two parallel branches. The first branch comprises transistor 1103 and 1107 and the second branch comprises transistor 1104 and 1106.

The gate terminals 1105, 1106 of transistors 1107, 1108 are joined together and the terminals are adapted to receive a cascode voltage. Thus, the input signals at the gate terminals 1105, 1106 are equal. The input signal or input voltage, which is provided at the gate terminals 1105, 1106, should be higher than the input signal provided at the input terminals 207″′ and 206″′. This input voltage may be constant over the time. Thus, the differential cascode pair 1107, 1108 keeps the differential pair 1103 and 1104 on a saturated operational level.

Similar to the circuit shown in FIG. 6, a plurality of stage circuits 1111 comprising biasing current source 1101, differential pair 1103, 1104 and cascoded differential pair 1107, 1108 can be inversely connected together. The output terminals 1109 and 1110 of circuit stage 1111 provide a high output resistance, that is seen from the output 1109, 1110. The connection of output terminals are similar to the inverse connection method described above.

FIG. 12 shows a further circuit stage according to an exemplary embodiment of the present invention.

The circuit stage 1209 comprises the switchable current source or switching unit 1201 implemented with NMOS transistor 1201. The source terminal of transistor 1201 is connected to a reference level 1202, which may be ground potential.

The drain terminal of transistor 1201 is connected in series to the source terminal of cascode transistor 1205, which receives at the input terminal 1206 a voltage, which is higher than the voltage at the gate of transistor 1201. Thus, an high output resistance of transistor 1205 is provided.

The output terminal or drain of transistor 1205 is connected in series to the source terminal of transistor 1203 and also to the source terminal of transistor 1204. Transistor 1203 and 1204 are implemented as differential pair. At input terminals 207″″ and 206″″ signals from an output stage of a pre-amplifier (not shown in FIG. 12) are provided.

The output terminals or drain terminals 1207, 1208 of transistor 1203, 1204 again can be inversely connected together to provide output signals as described above.

Exemplary fields of application of embodiments of the invention are moderate until high speed (100 MS/s−2 GS/s) analog-to-digital converters (ADC), with a medium resolution (7-10 bit). Direct application of these type of ADCs can be found in optical/magnetic data storage, high speed datalink and other read channels. As these converters can and will be used as building blocks for moderate speed and high resolution ADCs (>10 bit) the application area is broaden towards radio communication channels and video signal sampling.

Preferably the switching-unit is not positioned in the signal path but in the biasing path of the differential pairs. In combination with the current control, the sample rate may speed up. The circuit therefore may also work for high frequencies.

The higher efficiency reached by an embodiment of the invention can be traded for either a lower power consumption or increased bandwidth.

It should be noted that the term “comprising” does not exclude other elements or steps and the “a” or “an” does not exclude a plurality. Also elements described in association with different embodiments may be combined.

It should also be noted that reference signs in the claims shall not be construed as limiting the scope of the claims.

1. A switchable folding circuit for generating an output signal based on an input signal, the switchable folding circuit comprising a plurality of circuit stages, each of the circuit stages comprising:
a switching unit
a current source
a differential pair comprising an input terminal adapted to receive the input signal and an output terminal adapted to provide the output signal;
wherein, in each of the circuit stages, the differential, the current source and the switching unit are connected in series;
wherein adjacent ones of the plurality of circuit stages are inversely connected to one another.

2. The switchable folding circuit of claim 1, wherein the switching unit of a circuit stage is adapted to be closed if a primary signal is within a predetermined interval, which interval is corresponding to the switching unit; and
the predetermined interval is provided individually for each switching unit of the plurality of circuit stages.

3. The switchable folding circuit of claim 2, wherein each of the predetermined intervals is predetermined around a set reference value.

4. The switchable folding circuit of claim 2, wherein the output signal of a differential pair of a circuit stage is adapted in such a way that the output is linear if the primary signal varies in the predetermined interval, assigned to the differential pair.

5. The switchable folding circuit of claim 1, wherein the switching unit comprises a current mirror.

6. The switchable folding circuit of claim 1, wherein the switching unit and the current source of at least one of the plurality of circuit stages are formed as a common member.

7. The switchable folding circuit of claim 1, wherein, in each of the circuit stages, the differential pair is connected to the current source via the switching unit.

8. The switchable folding circuit of claim 1, adapted as an integrated circuit.

9. The switchable folding circuit of claim 1, wherein the input terminal is adapted as an input terminal pair.

10. The switchable folding circuit of claim 1, wherein the output terminal is adapted as an output terminal pair.

11. An analog-digital-converter, comprising a switchable folding circuit of claim 1.

12. The analog-digital-converter of claim 11, further comprising:
a pre-processing unit;
wherein the pre-processing unit is adapted to receive a primary signal; and
wherein the pre-processing unit is adapted to convert, for each circuit stage, the primary signal into the input signal for an assigned one of the differential pairs;
wherein, for each circuit stage, the switching unit is adapted to be closed if the primary signal is in a predetermined interval, which interval corresponds to the switching unit; and
wherein the predetermined intervals differ for each of the switching units of the plurality of circuit stages.

13. The analog-digital-converter of claim 11, further comprising:
a binary decoding unit;
wherein the binary decoding unit is adapted to receive the output signal; and
wherein the binary decoding unit is adapted to convert the output signal into a binary signal.

14. A method of operating a switchable folding circuit of claim 1, the method comprising:
receiving the input signal at the input terminals of the differential pairs;
selectively switching the switching units so as to bring, in a part of the circuit stages, a path of the differential pair, the current source and the switching unit in an electrically conductive state;
providing an output signal at the output terminals.
